(19) United States
(12) Patent Application Publication
(10) Pub. No.: US 2024/0234133 A1
(43) Pub. Date: Jul. 11, 2024

(54) TREATMENTS TO ENHANCE MATERIAL STRUCTURES

(71) Applicant: Applied Materials, Inc., Santa Clara, CA (US)

(72) Inventors: Steven C. H. HUNG, Sunnyvale, CA (US); Theresa Kramer GUARINI, San Jose, CA (US); Johanes F. SWENBERG, Los Gatos, CA (US)

(21) Appl. No.: 18/543,996

(22) Filed: Dec. 18, 2023

Related U.S. Application Data
(60) Provisional application No. 63/438,160, filed on Jan. 10, 2023.

(51) Int. Cl. H01L 21/02; C23C 8/02; C23C 8/16; C23C 8/80; C23C 16/02; C23C 16/40; C23C 16/455; C23C 16/56; C23C 28/04

(52) U.S. Cl. CPC H01L 21/02359; C23C 8/02; C23C 8/16; C23C 8/80; C23C 16/0209; C23C 16/405; C23C 16/45544; C23C 16/56; C23C 28/042; H01L 21/02164; H01L 21/02238; H01L 21/02307; H01L 21/02312; H01L 21/02337; H01L 21/0234; H01L 21/02181

(57) ABSTRACT

A method of forming a semiconductor structure includes performing a pre-treatment process, including annealing a surface of a substrate in a hydrogen (H₂) ambient, performing an interfacial formation process, including thermally oxidizing the pre-treated surface of the substrate to form an interfacial layer, and performing a post-treatment process, including annealing a surface of the formed interfacial layer in an ammonia (NH₃) ambient.

### CROSS-REFERENCE TO RELATED APPLICATIONS

This application claims priority to U.S. Provisional Application Ser. No. 63/438, 160 filed Jan. 10, 2023, which is herein incorporated by reference in its entirety.

### BACKGROUND

### Field

Embodiments described herein generally relate to semiconductor device fabrication, and more particularly, to systems and methods of forming a high quality high-κ dielectric layer in a semiconductor structure.

### Description of the Related Art

As metal-oxide-semiconductor field-effect transistors (MOSFETs) have decreased in size to achieve high device performance and low power consumption, the thickness of a traditional silicon dioxide (SiO₂) gate dielectric has decreased to its physical limit. As a result, replacing the silicon dioxide gate dielectric with a high-κ dielectric material has been inevitable to achieve further scaling. Among various high-κ dielectric materials, hafnium oxide (HfO₂) has been applied since the 45 nm MOSFET technology node due to its high dielectric constant and superior thermal stability on a silicon substrate. However, for further scaling of equivalent oxide thickness (EOT) for the 32 nm MOSFET technology node and beyond, simply decreasing the thickness of a high-κ dielectric layer is problematic due to an increase of leakage current through the high-κ dielectric layer.

Thus, there is a need for systems and methods that can be used to form thin (e.g., EOT less than 1 nm) high-κ dielectric layers having chemical structures that can be controlled to ensure desired structural and electrical properties.

### SUMMARY

Embodiments of the present disclosure provide a method of forming a semiconductor structure. The method includes performing a pre-treatment process, including annealing a surface of a substrate in a hydrogen (H₂) ambient, performing an interfacial formation process, including thermally oxidizing the pre-treated surface of the substrate to form an interfacial layer, and performing a post-treatment process, including annealing a surface of the formed interfacial layer in an ammonia (NH₃) ambient.

Embodiments of the present disclosure also provide a method of forming a semiconductor structure. The method includes performing a pre-clean process, including etching a surface of a substrate by a dry etch process using nitrogen trifluoride (NF₃) gas and a wet etch process using hydrochloric acid (HCl) solution and/or dilute hydrofluoric acid (DHF) solution, performing an interfacial layer module process to form an interfacial layer on the pre-cleaned surface of the substrate, wherein the interfacial layer module process includes performing a pre-treatment process, including annealing the pre-cleaned surface of the substrate in a hydrogen (H₂) ambient, performing an interfacial formation process, including thermally oxidizing the pre-treated surface of the substrate to form the interfacial layer, and performing a post-treatment process, including annealing a surface of the formed interfacial layer in an ammonia (NH₃) ambient, performing a hydration process, including annealing a surface of the interfacial layer in an ammonia (NH₃) and water (H₂O) ambient, and performing a deposition process, including depositing a high-κ dielectric layer on the hydrated surface of the interfacial layer.

Embodiments of the present disclosure further provide a processing system. The processing system includes a first processing chamber, a second processing chamber, a third processing chamber, a fourth processing chamber, a fifth processing chamber, a sixth processing chamber, and a system controller configured to perform, in the first processing chamber, a pre-clean process, including a dry etch process using nitrogen trifluoride (NF₃) gas and a wet etch process using hydrochloric acid (HCl) solution and/or dilute hydrofluoric acid (DHF) solution, in the second processing chamber, a pre-treatment process, including annealing the pre-cleaned surface of the substrate in a hydrogen (H₂) ambient, in the third processing chamber, an interfacial formation process, including thermally oxidizing the pre-treated surface of the substrate to form an interfacial layer, in the fourth processing chamber, a post-treatment process, including annealing a surface of the formed interfacial layer in an ammonia (NH₃) ambient, in the fifth processing chamber, a hydration process, including annealing a surface of the interfacial layer in an ammonia (NH₃) and water (H₂O) ambient, and in the sixth processing chamber, a deposition process, including depositing a high-κ dielectric layer on the hydrated surface of the interfacial layer. The pre-treatment process, the interfacial formation process, the post-treatment process, the hydration process, and the deposition process are performed in the processing system without breaking vacuum.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top-view diagram of an example multi-chamber processing system according to one embodiment.

FIG. 2 is a process flow diagram of a method of forming a semiconductor structure according to one embodiment.

FIGS. 3A, 3B, and 3C are schematic views of a semiconductor structure according to one embodiment.

FIG. 4 is a process flow diagram of interfacial layer (IL) module process according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

As gate structures scale to smaller dimensions, new material structures are being sought to provide improvements. The use of high-κ dielectric materials increases the dielectric constant of the gate structure over conventional gate structures that utilize materials such as silicon oxide. However, similar to silicon oxide, as the thickness of a gate structure is reduced, leakage currents increase. For example, gate leakage increases as the effective oxide thickness decreases. Hence, the inverse relationship between gate leakage and effective oxide thickness may form a limit on the performance of the transistor and the device produced.

High-κ dielectric materials may provide greater channel carrier concentration over silicon oxide at similar thicknesses. As the industry continues to seek lower effective oxide thicknesses without increased gate leakage, efforts to maximize a dielectric constant (also referred to as “κ-value”) of known high-κ materials are reaching limits due to morphological characteristics. Conventional technologies have struggled to overcome natural characteristics of high-κ materials, which may set an upper limit in the κ-value, and subsequent device remodeling in attempts to incorporate new films.

The embodiments described herein provide systems and methods for improving the characteristics of high-κ dielectric materials. By producing a high quality thin interface layer between a substrate and a high-κ dielectric layer, higher dielectric constants and subsequent improved device performance may be enabled.

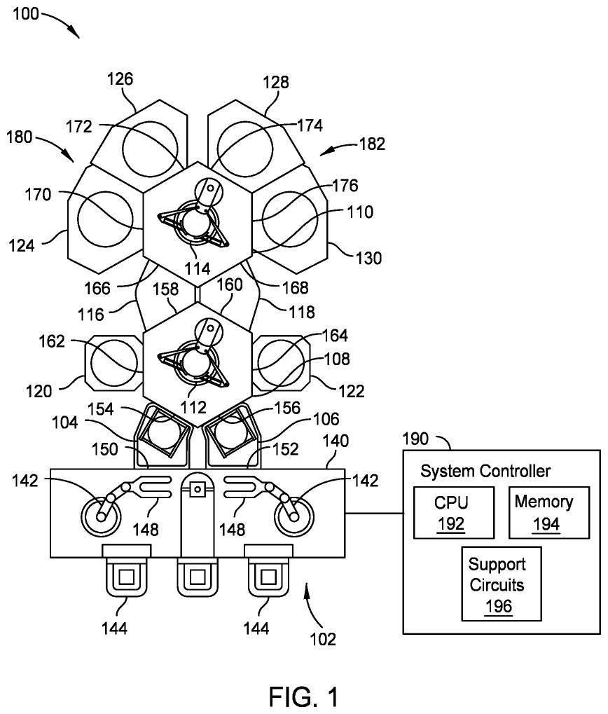

FIG. 1 is a schematic top-view diagram of an example of a multi-chamber processing system 100 according to some examples of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 100 to prevent contamination from moisture, organic or nonorganic trance species. Accordingly, the processing system 100 may provide for an integrated solution for some processing of wafers.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some examples, the processing chamber 122 can be capable of performing a cleaning process, the processing chamber 120 can be capable of performing an etch process, and the processing chambers 124, 126, 128, 130 can be capable of performing respective epitaxial growth processes. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

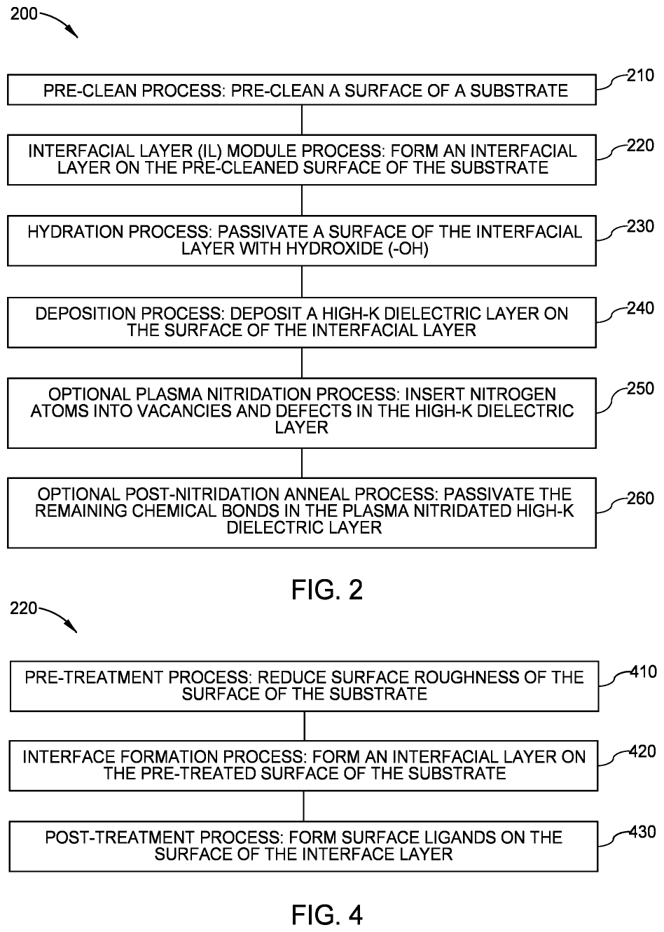

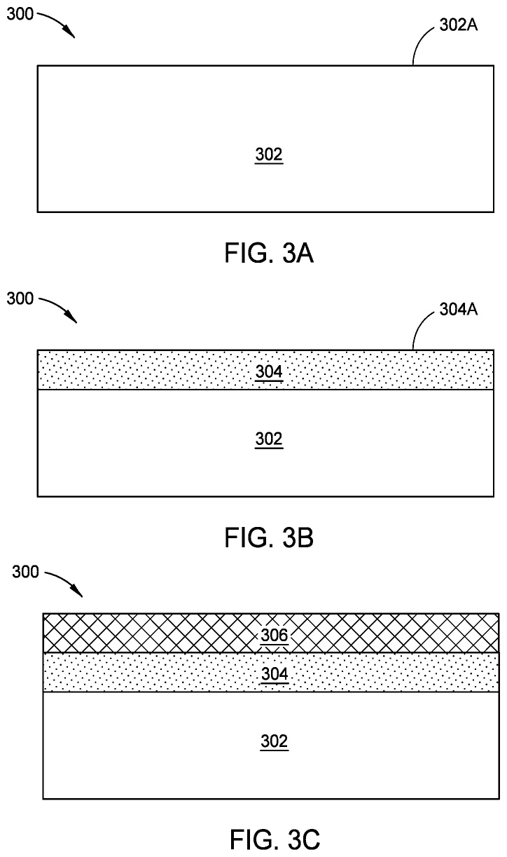

FIG. 2 is a process flow diagram of a method 200 of forming a semiconductor structure 300 according to one or more implementations of the present disclosure. FIGS. 3A, 3B, and 3C are cross-sectional views of a portion of the semiconductor structure 300 corresponding to various states of the method 200. It should be understood that FIGS. 3A, 3B, and 3C illustrate only partial schematic views of the semiconductor structure 300, and the semiconductor structure 300 may contain any number of transistor sections and additional materials having aspects as illustrated in the figures. It should also be noted although the method steps illustrated in FIG. 2 are described sequentially, other process sequences that include one or more method steps that have been omitted and/or added, and/or has been rearranged in another desirable order, fall within the scope of the embodiments of the disclosure provided herein.

The method 200 begins with a pre-clean process in block 210 to pre-clean a surface 302A of a substrate 302, as shown in FIG. 3A. The substrate 302 may include a material such as crystalline silicon (e.g., Si<100> or Si<111>), a doped or undoped silicon wafer, a patterned or non-patterned silicon wafer, strained silicon, silicon germanium, doped or undoped polysilicon, silicon on insulator (SOI), carbon doped silicon oxides, silicon nitride, doped silicon, germanium, gallium arsenide, glass, or sapphire. The substrate 302 may include a stack of silicon (Si) layers and silicon germanium (SiGe) layers that are alternately and repeatedly formed on the surface 302A of the substrate 302, as in gate all around (GAA) field-effect transistor (FET) structures.

The pre-clean process may include partially removing silicon germanium (SiGe) layers by a dry etch process, for example, a SiConi™ remote plasma assisted dry etch process, in which the surface 302A of the substrate 302 is exposed to nitrogen trifluoride (NF₃) gas, nitrogen (N₂) gas, or ammonia (NH₃) gas, and subsequently etching the surface 302A of the substrate 302 to remove oxide-containing contaminants (e.g., native oxide layers), by a wet etch process using an etch solution, such as hydrochloric acid (HCl) solution and/or dilute hydrofluoric acid (DHF) solution. The surface 302A of the substrate 302, pre-cleaned with DHF solution, may be hydrophobic (e.g., having no adhesion force with moisture) and have a large surface roughness, such as 5 Å to 8 Å.

The pre-clean process may be performed in a pre-clean chamber, such as Clarion™ or Siconi™ chamber, available from Applied Materials, Inc., located in Santa Clara, Calif. The pre-clean process may be performed without breaking vacuum environment in a multi-chamber processing system, such as the multi-chamber processing system 100 shown in FIG. 1, to prevent contamination from moisture, organic or nonorganic trance species.

In block 220, an interfacial layer (IL) module process is performed to form an interfacial layer 304 on the pre-cleaned surface of the substrate 302, as shown in FIG. 3B. The interfacial layer 304 formed in block 220 is a thin silicon oxide (SiO₂) layer, having a thickness of between about 3 Å and about 8 Å, for example, about 4 Å, corresponding to one or more monolayers of silicon oxide. The interfacial layer 304 may act as a nucleation layer of a high-κ dielectric layer 306 (shown in FIG. 3C) to be deposited thereon and improve quality (e.g., such as interface state density, accumulation capacitance, frequency dispersion, and leakage current) of the interface between the substrate 302 and the high- dielectric layer 306.

Since the surface 302A of the substrate 302 may be hydrophobic and have a large surface roughness, the IL module process includes a pre-treatment process to smooth the surface 302A of the substrate 302, prior to forming the interfacial layer 304, and a post-treatment process to form surface ligands on a surface 304A (e.g., silicon oxide (SiO₂)) of the interfacial layer 304 subsequent to forming the interfacial layer 304, as discussed in detail below. A high quality of a conformal thin interfacial layer 304 can be formed on a smoothed surface of the substrate 302, and its thickness can be precisely controlled.

In block 230, a hydration process is performed to passivate a surface 304A of the interfacial layer 304 formed in block 220 with hydroxide (—OH), which catalyze bonding of the surface 304A of the interfacial layer 304 with metal-containing precursor used to form a high-κ dielectric layer 306 (shown in FIG. 3C) on the surface 304A of the interface layer in the deposition process in block 240.

The hydration process may include exposing the substrate 302 to an ammonia (NH₃) and water (H₂O) ambient, in a processing chamber, such as such as Clarion™ chamber, available from Applied Materials, Inc., located in Santa Clara, Calif. The hydration process may be performed without breaking vacuum environment in a multi-chamber processing system, such as the multi-chamber processing system 100 shown in FIG. 1, to prevent contamination from moisture, organic or nonorganic trance species.

The rapid thermal anneal process may be performed at a temperature of between about 15° C.and about 60° C., and at a pressure of between about 5 Torr and 300 Torr.

In block 240, a deposition process is performed to deposit a high-κ dielectric layer 306 on the hydrated surface 304A of the interfacial layer 304, as shown in FIG. 3C. The high-κ dielectric layer 306 may be formed of high-κ dielectric material, such as hafnium dioxide (HfO₂), zirconium dioxide (ZrO₂), ytterbium oxide (Y₂O₃), or aluminum oxide (Al₂O₃).

The deposition process may include an atomic layer deposition (ALD) process, in which a metal-containing precursor and an oxygen-containing precursor are alternately delivered to the exposed surface of the semiconductor structure 300. In some embodiments, the metal-containing precursor is purged prior to delivering the oxygen-containing precursor. The metal may be a transition metal, such as hafnium (Hf), zirconium (Zr), or titanium (Ti), a rare-earth metal, such as lanthanum (La), ytterbium (Yb), or yttrium (Y), an alkaline earth metal, such as strontium (Sr), or other metal such as aluminum (Al). For the oxidant, any oxygen-containing precursor may be used that may react with the metal. For example, the oxygen-containing precursor may be or include water, diatomic oxygen, ozone, a hydroxyl-containing precursor or alcohol, nitrogen-and-oxygen-containing precursors, plasma-enhanced oxygen including locally or remotely enhanced oxygen, or any other material including oxygen that may be incorporated with the metal to produce a layer of an oxide of the metal over the substrate 302. In one example, the metal-containing precursor is hafnium tetrachloride (HfCl₄) and the oxidant is DI water (H₂O) to form a hafnium dioxide (HfO₂) layer. The ALD process may be performed at a temperature of between about 200° C.and about 400° C., for example, about 270° C. The high-κ dielectric layer 306, as deposited by the ALD process, may be amorphous and have a thickness of between about 10 Å and about 30 Å.

The deposition process may be performed in a processing chamber, such as the processing chamber 120, 122, 124, 126, 128, or 130 shown in FIG. 1. The deposition process may be performed without breaking vacuum environment in a multi-chamber processing system, such as the multi-chamber processing system 100 shown in FIG. 1, to prevent contamination from moisture, organic or nonorganic trance species.

In block 250, an optional plasma nitridation process is performed to insert nitrogen atoms into vacancies and defects in the high-κ dielectric layer 306. The plasma nitridation process may be a decoupled plasma nitridation (DPN) process performed in a DPN chamber such as CENTURA® DPN chamber, available from Applied Materials, Inc., located in Santa Clara, Calif.

The plasma nitridation process exposes the deposited high-κ dielectric layer 306 to nitrogen plasma, which may allow nitrogen radicals or nitrogen atoms to be incorporated within the high-κ dielectric layer 306, throughout the thickness of the high-κ dielectric layer 306. During the plasma nitridation process, nitrogen atoms may form metastable bonds with oxygen (O). Gases that may be used in the plasma process include nitrogen containing gas, such as nitrogen (N₂), ammonia (NH₃), or mixtures thereof. In one example, the nitrogen gas is ammonia (NH₃) mixed with about 3% to about 8% of nitrogen (N₂). The plasma nitridation process may not change a thickness of the high-κ dielectric layer 306 as a result of the nitrogen incorporation to vacancies and defects in the as-deposited high-κ dielectric layer 306.

The plasma nitridation process may be performed for between about 10 seconds and about 300 seconds, at a temperature of between about 0° C.and about 500° C.

In block 260, an optional post-nitridation anneal process is performed to passivate the remaining chemical bonds in the plasma nitridated high-κ dielectric layer 306.

The post-nitridation anneal process may include a spike thermal anneal process in a nitrogen (N₂) and argon (Ar) ambient, performed in a rapid thermal processing (RTP) chamber, such as RadOx™ chamber, available from Applied Materials, Inc., located in Santa Clara, Calif.

The spike thermal anneal process may be performed for between about 1 second and about 30 seconds, at a temperature of between about 700° C.and about 900° C., and at a pressure of between about 0.5 Torr and 780 Torr.

FIG. 4 is a process flow diagram of the IL module process shown in block 220 of the method 200 according to one or more implementations of the present disclosure.

The IL module process begins with a pre-treatment process in block 410 to reduce surface roughness of the surface 302A of the substrate 302 The surface 302A of the substrate 302 that has been pre-cleaned by an etch process in block 210 may be rough. The pre-treatment process may reduce the surface roughness of the surface 302A of the substrate, prior to formation of the interfacial layer 304 on the surface 302A of the substrate 302.

The pre-treatment process may include a spike thermal anneal process in a hydrogen (H₂) ambient, to induce silicon (Si) atoms to migrate on the surface 302A of the substrate 302 and enhance smoothness of the surface 302A of the substrate 302. The spike thermal anneal process may be performed for between about 10 seconds and about 100 seconds, at a temperature of between about 500° C. and about 900° C., and at a pressure of between about 5 Torr and 80 Torr.

The pre-treatment process may be performed in a rapid thermal processing (RTP) chamber, such as RadOx™ chamber, available from Applied Materials, Inc., located in Santa Clara, Calif. The pre-treatment process may be performed without breaking vacuum environment in a multi-chamber processing system, such as the multi-chamber processing system 100 shown in FIG. 1, to prevent contamination from moisture, organic or nonorganic trance species.

In block 420, an interface formation process is performed to form the interfacial layer 304 on the pre-treated surface 302A of the substrate 302, as shown in FIG. 3A.

The interface formation process may include a suitable thermal oxidation process to oxidize the surface 302A of the substrate 302, such as an enhanced in-situ steam generation (eISSG) process utilizing nitrous oxide (N₂O) gas and hydrogen (H₂) gas at a temperature of between about 500° C.and about 800° C.and a pressure of between 1 Torr and about 30 Torr. In some embodiments, the interfacial layer 304 may be formed by a rapid thermal oxidation (RTO) process utilizing O₂ gases at a temperature of between about 500° C. and about 800° C. The interfacial layer 304 formed at the high temperature in block 420 may be dense and not increase its thickness in the subsequent processes.

The interface formation process may be performed in a processing chamber, such as the processing chamber 120, 122, 124, 126, 128, or 130 shown in FIG. 1. The interface formation process may be performed without breaking vacuum environment in a multi-chamber processing system, such as the multi-chamber processing system 100 shown in FIG. 1, to prevent contamination from moisture, organic or nonorganic trance species.

In block 430, a post-treatment process is performed to form surface ligands on the surface 304A of the interfacial layer 304, which catalyze bonding of the surface 304A of the interfacial layer 304 with metal-containing precursor used to form a high-κ dielectric layer 306 on the surface 304A of the interface layer in the deposition process in block 240. In one example, for a hafnium tetrachloride (HfCl₄) precursor to form a hafnium dioxide (HfO₂) layer, NH₂ ligands are formed to promote nucleation of hafnium tetrachloride (HfCl₄) on the surface 304A of the interfacial layer 304, by NH₂ ligands terminating silicon (Si) dangling bonds at the surface 304A of the substrate 302. Proper nucleation of the hafnium tetrachloride (HfCl₄) on the surface 304A of the interfacial layer 304 leads to formation of the high-κ dielectric layer 306 without defects. Proper nucleation of other metal-containing precursors of metal halide (e.g., chloride, fluoride, bromide), such as zirconium chloride (ZrCl₄), titanium tetrachloride (TiCl₄) on the surface 304A of the interfacial layer 304 may be promoted similarly by NH₂ ligands terminating silicon (Si) dangling bonds.

The post-treatment process may include a spike thermal anneal process in an ammonia (NH₃) ambient, to form surface NH₂ ligands on the surface 304A of the interfacial layer 304. The spike thermal anneal process may be performed for between about 15 seconds and about 60 seconds, at a temperature of between about 500° C.and about 800° C., and at a pressure of between about 2 Torr and about 50 Torr.

The post-treatment process may be performed in a rapid thermal processing (RTP) chamber. The post-treatment process may be performed without breaking vacuum environment in a multi-chamber processing system, such as the multi-chamber processing system 100 shown in FIG. 1, to prevent contamination from moisture, organic or nonorganic trance species.

In the embodiments described herein, the systems and the methods of forming high-quality thin high-κ dielectric layers are provided. The properties of such high-κ dielectric layers may be well controlled. For example, the nitridation process in block 260 may be controlled to provide a nitrogen incorporation in the high-κ dielectric layer 306 of between about 3 atomic % and about 20 atomic %, to achieve a higher κ-value than a higher nitrogen incorporation, and to suppress formation grains in the high-κ dielectric layer 306 having a size larger than about 20 Å.

While the foregoing is directed to embodiments of the present disclosure, other and further embodiments of the disclosure may be devised without departing from the basic scope thereof, and the scope thereof is determined by the claims that follow.

1. A method of forming a semiconductor structure, the method comprising:
performing a pre-treatment process, comprising annealing a surface of a substrate in a hydrogen (H₂) ambient;
performing an interfacial formation process, comprising thermally oxidizing the pre-treated surface of the substrate to form an interfacial layer; and
performing a post-treatment process, comprising annealing a surface of the formed interfacial layer in an ammonia (NH₃) ambient.

2. The method of claim 1, wherein the pre-treatment process, the interfacial formation process, and the post-treatment process are performed in a processing system without breaking vacuum.

3. The method of claim 1, wherein the substrate comprises silicon (Si) and the interfacial layer comprises silicon oxide (SiO₂).

4. The method of claim 3, wherein
the interfacial formation process comprises thermally oxidizing the substrate utilizing nitrous oxide (N₂O) gas and hydrogen (H₂) gas.

5. The method of claim 3, wherein the interfacial layer has a thickness of between 3 Å and 8 Å.

6. The method of claim 1, wherein the pre-treatment process is performed for between 30 seconds and 100 seconds, at a temperature of between 500° C.and 900° C., and at a pressure of between 5 Torr and 80 Torr.

7. The method of claim 1, wherein the post-treatment process is performed for between 15 seconds and 60 seconds, at a temperature of between 500° C.and 800° C., and at a pressure of between about 2 Torr and 50 Torr.

8. A method of forming a semiconductor structure, the method comprising:
performing a pre-clean process, comprising etching a surface of a substrate by a dry etch process using nitrogen trifluoride (NF₃) gas and a wet etch process using hydrochloric acid (HCl) solution and/or dilute hydrofluoric acid (DHF) solution;
performing an interfacial layer module process to form an interfacial layer on the pre-cleaned surface of the substrate, wherein the interfacial layer module process comprises:
performing a pre-treatment process, comprising annealing the pre-cleaned surface of the substrate in a hydrogen (H₂) ambient;
performing an interfacial formation process, comprising thermally oxidizing the pre-treated surface of the substrate to form the interfacial layer; and
performing a post-treatment process, comprising annealing a surface of the formed interfacial layer in an ammonia (NH₃) ambient;
performing a hydration process, comprising annealing a surface of the interfacial layer in an ammonia (NH₃) and water (H₂O) ambient; and
performing a deposition process, comprising depositing a high-κ dielectric layer on the hydrated surface of the interfacial layer.

9. The method of claim 8, wherein the interfacial layer module process, the hydration process, and the deposition process are performed in a processing system without breaking vacuum.

10. The method of claim 8, wherein
the substrate comprises silicon (Si) and the interfacial layer comprises silicon oxide (SiO₂) having a thickness of between 3 Å and 8 Å, and
the interfacial formation process comprises thermally oxidizing the substrate utilizing nitrous oxide (N₂O) gas and hydrogen (H₂) gas.

11. The method of claim 8, wherein the pre-treatment process is performed for between 30 seconds and 100 seconds, at a temperature of between 500° C.and 900° C., and at a pressure of between 10 Torr and Torr.

12. The method of claim 8, wherein the post-treatment process is performed for between 15 seconds and 60 seconds, at a temperature of between 500° C.and 800° C., and at a pressure of between about 2 Torr and 50 Torr.

13. The method of claim 8, wherein the high-κ dielectric layer comprises hafnium oxide (HfO₂).

14. The method of claim 8, further comprising:
performing a plasma nitridation process, comprising exposing the deposited high-κ dielectric layer to nitrogen plasma using a mixture of nitrogen (N₂) and ammonia (NH₃) gas; and
performing a post-nitridation anneal process, comprising annealing the plasma nitridated surface of the high-κ dielectric layer in a nitrogen (N₂) and argon (Ar) ambient at a temperature of between of between 700° C.and 900° C.

15. A processing system, comprising:
a first processing chamber;
a second processing chamber;
a third processing chamber;
a fourth processing chamber;
a fifth processing chamber;
a sixth processing chamber; and
a system controller configured to perform:
in the first processing chamber, a pre-clean process, comprising etching a surface of a substrate by a dry etch process using nitrogen trifluoride (NF₃) gas and a wet etch process using hydrochloric acid (HCl) solution and/or using dilute hydrofluoric acid (DHF) solution;
in the second processing chamber, a pre-treatment process, comprising annealing the pre-cleaned surface of the substrate in a hydrogen (H₂) ambient;
in the third processing chamber, an interfacial formation process, comprising thermally oxidizing the pre-treated surface of the substrate to form an interfacial layer;
in the fourth processing chamber, a post-treatment process, comprising annealing a surface of the formed interfacial layer in an ammonia (NH₃) ambient;
in the fifth processing chamber, a hydration process, comprising annealing a surface of the interfacial layer in an ammonia (NH₃) and water (H₂O) ambient; and
in the sixth processing chamber, a deposition process, comprising depositing a high-κ dielectric layer on the hydrated surface of the interfacial layer,
wherein the pre-treatment process, the interfacial formation process, the post-treatment process, the hydration process, and the deposition process are performed in the processing system without breaking vacuum.

16. The processing system of claim 15, wherein
the substrate comprises silicon (Si) and the interfacial layer comprises silicon oxide (SiO₂) having a thickness of between 3 Å and _8 Å, and
the interfacial formation process comprises thermally oxidizing the substrate utilizing nitrous oxide (N₂O) gas and hydrogen (H₂) gas.

17. The processing system of claim 15, wherein the pre-treatment process is performed for between 30 seconds and 100 seconds, at a temperature of between 500° C. and 900° C., and at a pressure of between 10 Torr and Torr.

18. The processing system of claim 15, wherein the post-treatment process is performed for between 15 seconds and 60 seconds, at a temperature of between 500° C. and 800° C., and at a pressure of between about 2 Torr and 50 Torr.

19. The processing system of claim 15, wherein the high-κ dielectric layer comprises hafnium oxide (HfO₂).

20. The processing system of claim 15, further comprising:
a seventh processing chamber; and
an eighth processing chamber, wherein the system controller is further configured to perform:
in the seventh processing system, a plasma nitridation process, comprising exposing the deposited high-κ dielectric layer to nitrogen plasma using a mixture of nitrogen (N₂) and ammonia (NH₃) gas; and
in the eighth processing system, a post-nitridation anneal process, comprising annealing the plasma nitridated surface of the high-κ dielectric layer in a nitrogen (N₂) and argon (Ar) ambient at a temperature of between of between 700° C. and 850° C.
